(19) United States
(12) Patent Application Publication
(10) Pub. No.: US 2008/0017945 A1
(43) Pub. Date: Jan. 24, 2008

(54) METHOD FOR FABRICATING COLOR FILTERS

(76) Inventors: Yi-Tyng Wu, Chia-I City (TW); Fu-Kuo Ou, Hsinchu City (TW); Ta-Shuang Kuan, Hsin-Chu Hsien (TW)

Correspondence Address: NORTH AMERICA INTELLECTUAL PROPERTY CORPORATION, P.O. BOX 506, MERRIFIELD, VA, 22116, US

(21) Appl. No.: 11/459,635

(22) Filed: Jul. 24, 2006

(51) Int. Cl. H01L 31/00; G02B 5/20

(52) U.S. Cl. 257/440; 430/7

(57) ABSTRACT

A method for fabricating a color filter is disclosed. First, a substrate having a dielectric layer and a passivation thereon is provided. Next, a first pattern transfer process is performed to form a trench in the dielectric layer and the passivation layer, and a color filter is formed in the trench, in which the color filter partially covers the surface of the passivation layer. Next, a chemical mechanical polishing process is performed to planarize the color filter, such that the surface of the color filter is even with the surface of the passivation layer.

### BACKGROUND OF THE INVENTION

1. Field of the Invention

The invention relates to a method for fabricating color filters.

2. Description of the Prior Art

As the development of electronic products progresses, the demand for related components has increased as well. For example, as the development of digital cameras and scanners progresses, the demand for image sensor increases accordingly. In general, today's image sensors in common usage are divided into two main categories: charge coupled device (CCD) sensors and CMO image sensors (CIS). The application of CMOS image sensors has increased significantly for several reasons. Primarily, CMOS image sensors have certain advantages of offering low operating voltage, low power consumption, and the ability for random access. Additionally, CMOS image sensors are currently capable of integration with the semiconductor fabrication process.

The CMOS image sensor separates (i.e., classifies) incident light into a combination of light of different wavelengths. The light of different wavelengths is received by respective sensing elements and is subsequently transferred into digital signals of different intensities. For example, the CMOS image sensor can consider incident light as a combination of red, blue, and green light. Those wavelengths are subsequently received by photodiodes, and then transformed into digital signals. However, in order to separate incident light, a monochromatic color filter array (CFA) must be set above every optical sensor element.

Please refer to FIG. 1 through FIG. 3. FIG. 1 through FIG. 3 are perspective diagrams showing a means of utilizing a lift-off method to fabricate a color filter array according to the prior art. As shown in FIG. 1, a patterned photoresist 12 is formed on the surface of a substrate 10, in which the substrate 10 includes a plurality of optically sensitive elements (not shown) and metal interconnects (not shown) thereon. Next, as shown in FIG. 2, a color filter 14, such as a dichroic film is deposited on the surface of the substrate 10 and the photoresist 12. As shown in FIG. 3, a stripping process is performed thereafter by utilizing a photoresist stripper to remove the patterned photoresist 12 and the color filter 14 and form a color filter pattern 16.

However, the temperature involved to deposit the color filter, when the conventional lift-off process is performed, is maintained well below 150° C. This temperature ceiling is necessary for preventing the color filter material from degrading or deformation. Due to the temperature limitation, the color filter array fabricated by the lift-off process is unable to provide color filters with optimal optical property.

Please refer to FIG. 4 through FIG. 9. FIG. 4 through FIG. 9 are perspective diagrams showing another means of fabricating a color filter array according to the prior art. As shown in FIG. 4, a substrate 20 is provided, in which the substrate 20 includes a plurality of optically sensitive elements (not shown) and metal interconnects (not shown) formed thereon. Next, a green filter layer 22 and a photoresist 24 are formed on the substrate 20. As shown in FIG. 5, a pattern transfer process is performed, such as utilizing a patterned mask (not shown) to perform an exposure and development process on the photoresist 24 and form a plurality of trenches 26 in the photoresist 24. Next, as shown in FIG. 6, an etching process is performed to remove the green filter layer 22 not covered by the photoresist 24 for forming a plurality of green color filters 23. The photoresist 24 is stripped thereafter.

Next, as shown in FIG. 7, a blue filter layer 28 is deposited on the green filter 23 and the substrate 20. As shown in FIG. 8, another pattern transfer process is performed by forming a photoresist 30 on the blue filter layer 28 and then forming a plurality of trenches 32 in the photoresist 30. Next, an etching process is performed to remove the blue filter layer 28 not covered by the photoresist 30 to form a plurality of blue filters 34 between the green filters 23, as shown in FIG. 9. The patterned photoresist 30 is stripped thereafter. Subsequently, a series of deposition and pattern transfer processes can be performed to form a plurality of red filters (not shown) between the blue filters 34 and the green filters 23, thereby completing the fabrication of a color filter array.

However, by performing a series of pattern transfer and etching process on the color filter material directly, the etchant used by the aforementioned method is likely to eat away the surrounding area of each color filter and result in a plurality of uneven cavities. Consequently, the fabricated color filter array will not be able to maintain a continuous and even surface, thereby reducing the resolution and optical quality of the end product.

### SUMMARY OF THE INVENTION

It is therefore an objective of the present invention to provide a method of fabricating a color filter array for improving the resolution and optical property of the conventional color filter array.

According to the present invention, a method for fabricating a color filter is disclosed. First, a substrate having a dielectric layer and a passivation thereon is provided. Next, a first pattern transfer process is performed to form a trench in the dielectric layer and the passivation layer, and a color filter is formed in the trench, in which the color filter partially covers the surface of the passivation layer. Next, a chemical mechanical polishing process is performed to planarize the color filter, such that the surface of the color filter is even with the surface of the passivation layer.

By performing a pattern transfer process to form a trench in the dielectric layer disposed on the substrate, depositing a color filter in the trench, and performing a chemical mechanical polishing process to planarize the surface of the color filter, the present invention is able to improve the problem of poor resolution and optically quality of color filters fabricated by conventional lift-off process or regular etching process. The present invention can be further applied to various optical products involving the utilization of color filters, including CMOS image sensors, charge coupled devices, and liquid crystal on silicon (LCOS) displays.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 through FIG. 3 are perspective diagrams showing a means of utilizing a lift-off method to fabricate a color filter array according to the prior art.

FIG. 4 through FIG. 9 are perspective diagrams showing another means of fabricating a color filter array according to the prior art.

FIG. 10 through FIG. 14 are perspective diagrams showing a method of fabricating a color filter array according to the present invention.

FIG. 15 through FIG. 24 are perspective diagrams showing a method of fabricating a CMOS image sensor according to the present invention.

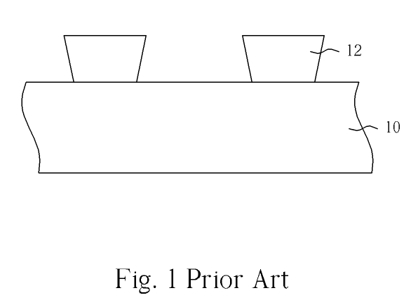

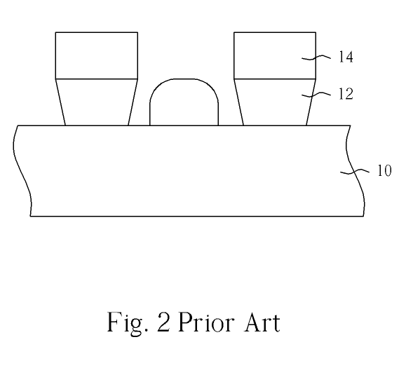

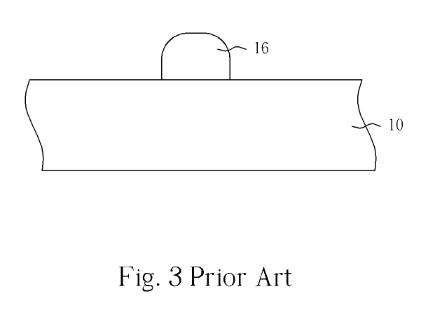

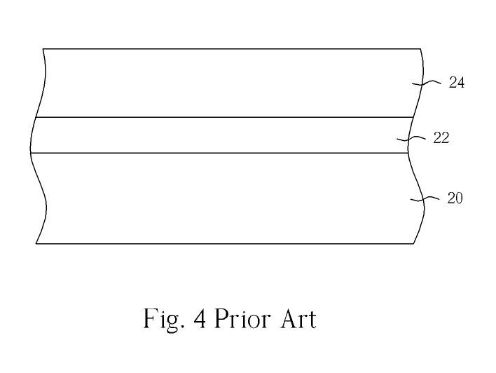

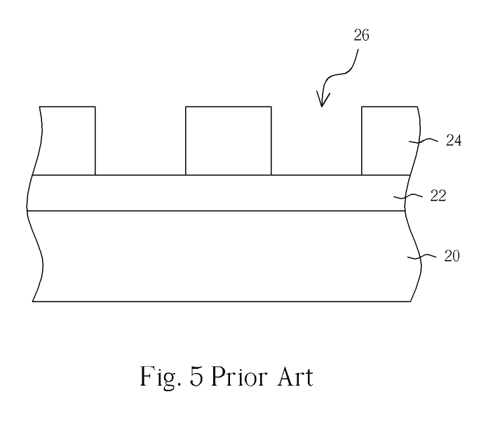

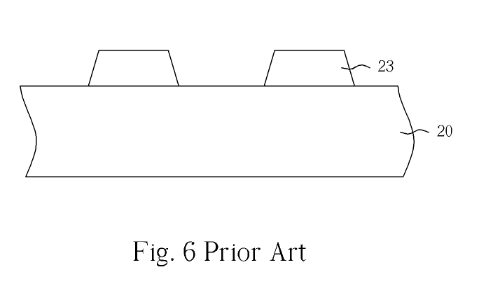

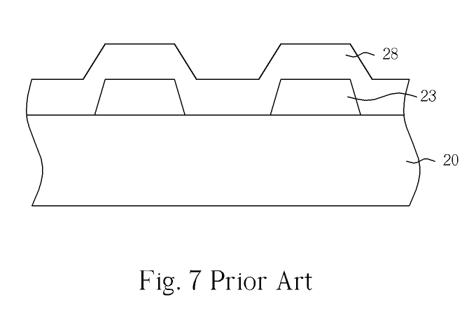

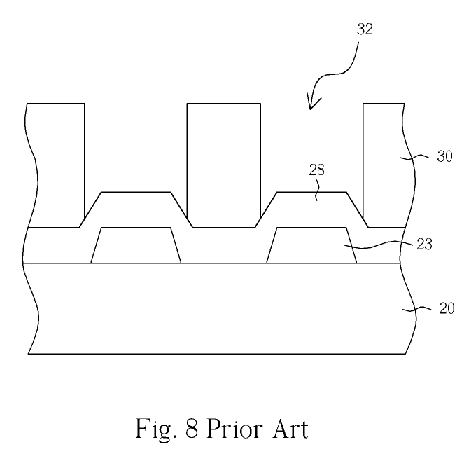

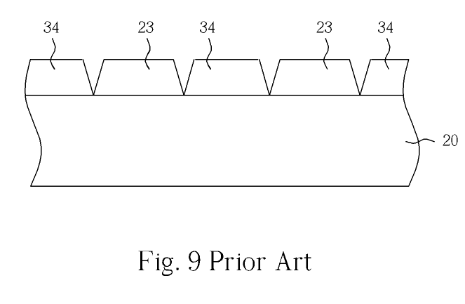

### DETAILED DESCRIPTION

Certain terms are used throughout the following description and claims to refer to particular system components. As one skilled in the art will appreciate, consumer electronic equipment manufacturers may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . ” The terms “couple” and “couples” are intended to mean either an indirect or a direct electrical connection. Thus, if a first device couples to a second device, that connection may be through a direct electrical connection, or through an indirect electrical connection via other devices and connections.

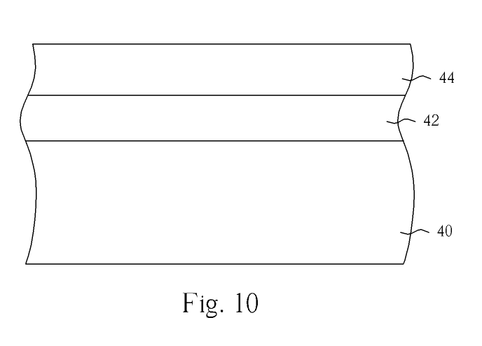

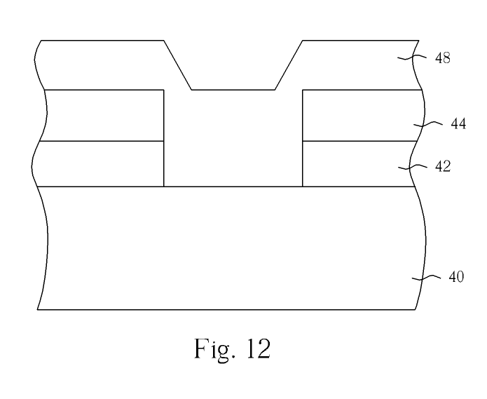

Please refer to FIG. 10 through FIG. 14. FIG. 10 through FIG. 14 are perspective diagrams showing a method of fabricating a color filter array according to the present invention. As shown in FIG. 10, a substrate 40 having a plurality of optical elements (not shown) arranged according to a matrix and a plurality of metal interconnects (not shown) are provided. A dielectric layer 42 and a passivation layer 44 are formed on the substrate 40 thereafter.

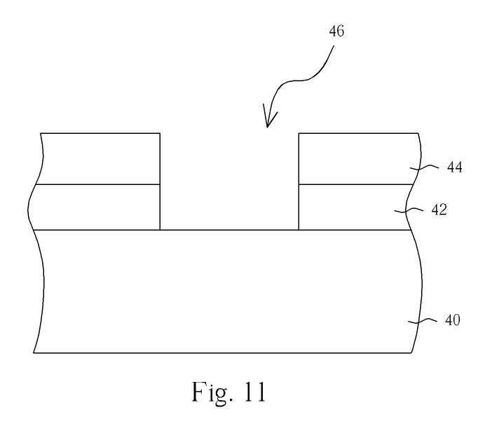

Next, as shown in FIG. 11, a pattern transfer process is performed. First, a patterned photoresist (not shown) is disposed on the surface of the passivation layer 44, and an etching process is performed by utilizing the patterned photoresist as a mask to remove a portion of the passivation layer 44 and the dielectric layer 42 not covered by the patterned photoresist for forming a trench 46 in the passivation layer 44 and the dielectric layer 42. After stripping the patterned photoresist, a color film 48, such as a dichroic film is deposited in the trench 46. The color film 48 can be selected from a group consisting of red color filter, blue color filter, green color filter, cyan color filter, magenta color filter, and yellow color filter.

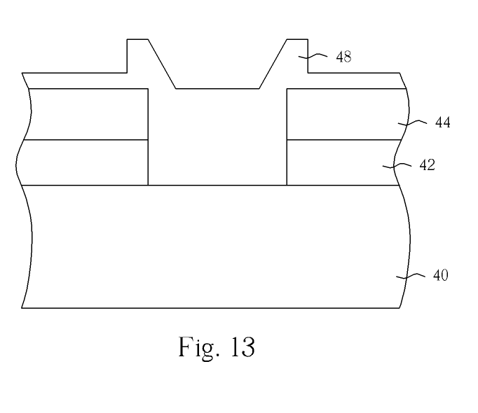

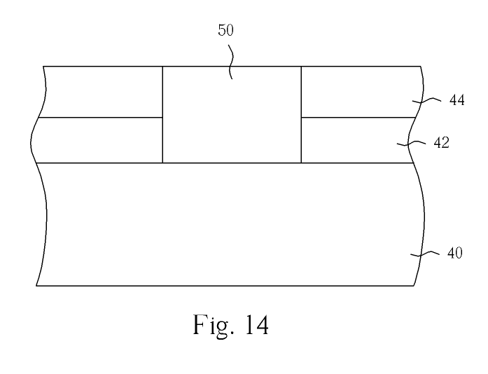

As shown in FIG. 13, another pattern transfer process is performed by first forming a patterned photoresist (not shown) on the color film 48. Next, an etching process is performed to remove a portion of the color film 48 not covered by the patterned photoresist. After stripping the patterned photoresist, as shown in FIG. 14, a chemical mechanical polishing (CMP) process is performed to planarize the surface of the color film 48. Consequently, the surface of the color film 48 is even with the surface of the passivation layer 44 and the color film 48 is embedded within the passivation layer 44 and the dielectric layer, thereby completing the fabrication of a color filter 50. Alternatively, the present invention is able to perform the chemical mechanical polishing process as soon as the color film 48 is deposited in the trench 46 and utilize the CMP process to planarize the surface of the color film 48, such that the surface of the color film 48 is even with the surface of the passivation layer 44. Subsequently, the dielectric layer 42 and the passivation layer 44 surrounding the color filter 50 can be removed afterwards, and a series of pattern transfer and etching processes can be performed repeatedly to form a plurality of color filters of different color adjacent to the color filter 50, thus completing the fabrication of a color filter array.

It should be noted that the present invention first performs a pattern transfer process on a substrate to form a trench in the dielectric layer above the substrate, deposit a color film in the trench, and performs a chemical mechanical polishing process to planarize the surface of the color film. Ideally, the present invention is able to improve the conventional problem of utilizing the lift-off or straight etching method to fabricate a color filter array and result in poor resolution or unsatisfactory optical quality.

According to the preferred embodiment of the present invention, depending on different optical elements fabricated on the substrate, such as photodiodes or micro-displays, the color filter array can be applied to various end products, including CMOS images sensors, charge coupled devices (CCD), or liquid crystal on silicon (LCOS) display panels.

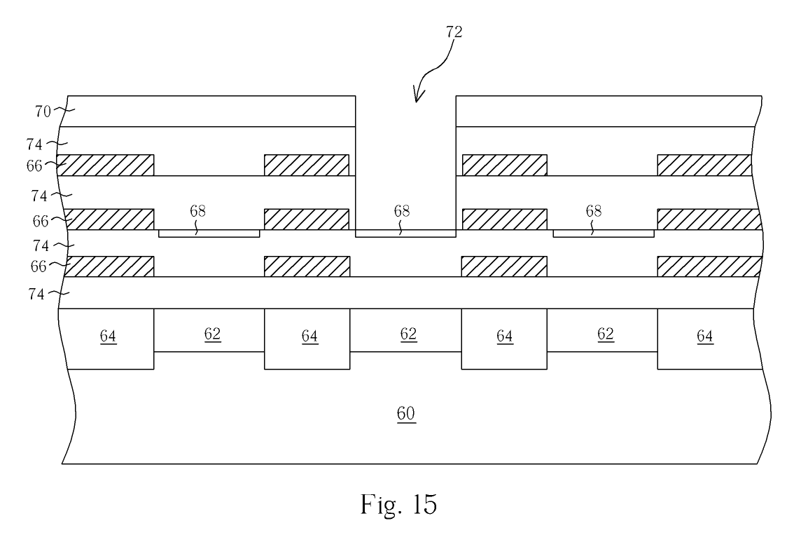

A process for fabricating a color filter array of a CMO image sensor is described below. Please refer to FIG. 15 through FIG. 24. FIG. 15 through FIG. 24 are perspective diagrams showing a method of fabricating a CMOS image sensor according to the present invention. As shown in FIG. 15, a semiconductor substrate 60 is provided, in which the semiconductor substrate 60 includes a plurality of photodiodes 62 for collecting light, a plurality of CMOS transistors (not shown), and a plurality of shallow trench isolation (STI) 64. Next, a metal interconnective process is performed to form a plurality of inter-metal dielectric (IMD) 74 on the semiconductor substrate 60, in which the inter-metal dielectric 74 includes a plurality of metal layers 66 disposed above the shallow trench isolation 64 and a plurality of etch stop layers 68 disposed above the photodiodes 62. The etch stop layers 68 can be composed of photosensitive or non-photosensitive materials.

Next, a passivation layer 70 composed of silicon nitride or silicon oxide is disposed on the metal layer 66 and the inter-metal dielectric 74, and a pattern transfer process is performed by first forming a patterned photoresist (not shown) on the passivation layer 70, and performing an etching process on the passivation layer 70 and the inter-metal dielectric 74 until reaching the etch stop layer 68 to form a trench 72 in the passivation layer 70 and the inter-metal dielectric 74. It should be noted that if the etch stop layer 68 is composed of a non-photosensitive material, the etch stop layer 68 can be removed simultaneously while the trench 72 is formed, thereby allowing the light to penetrate through the trench 72 and reach the photodiodes 62.

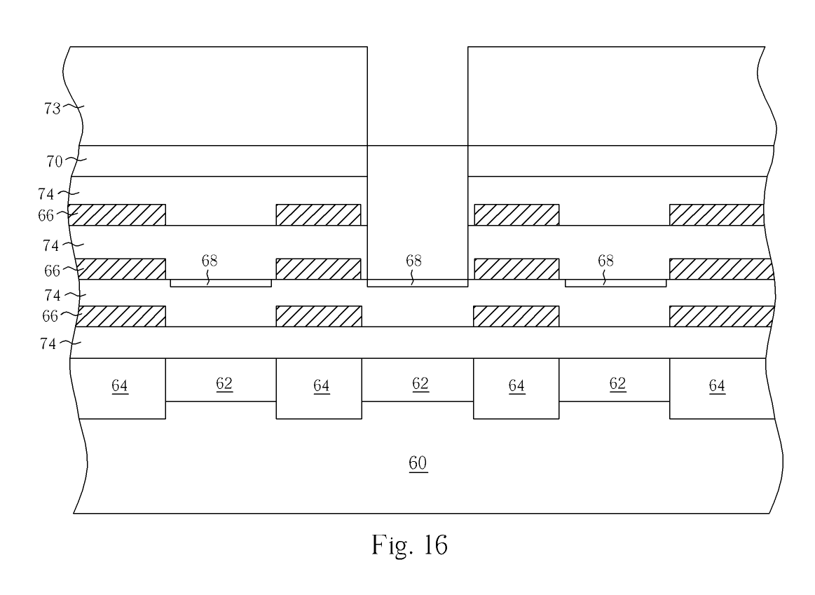

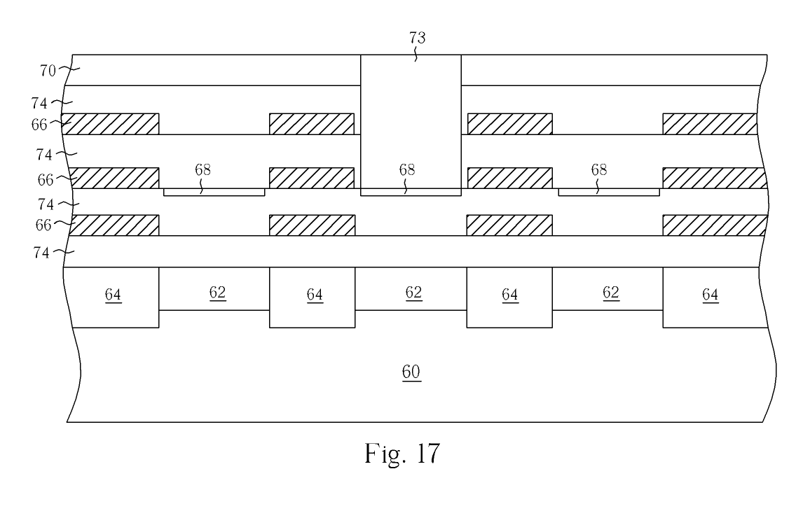

After the patterned photoresist is stripped, as shown in FIG. 16, a color film, such as a green color filter 73 composed of green dichroic film, is deposited on the passivation layer 70 and in the trench 72. According to an embodiment of the present invention, the color film can be selected from a group consisting of red color filter, blue color filter, green color filter, cyan color filter, magenta color filter, and yellow color filter. Next, as shown in FIG. 17, a chemical mechanical polishing process is performed to planarize the green color filer 73 disposed on the surface of the passivation layer 70, such that the green color filter 73 deposited in the trench 72 is even with the surface of the passivation layer 70, and the green color filter 73 is embedded within the passivation layer 70 and the dielectric layer 74.

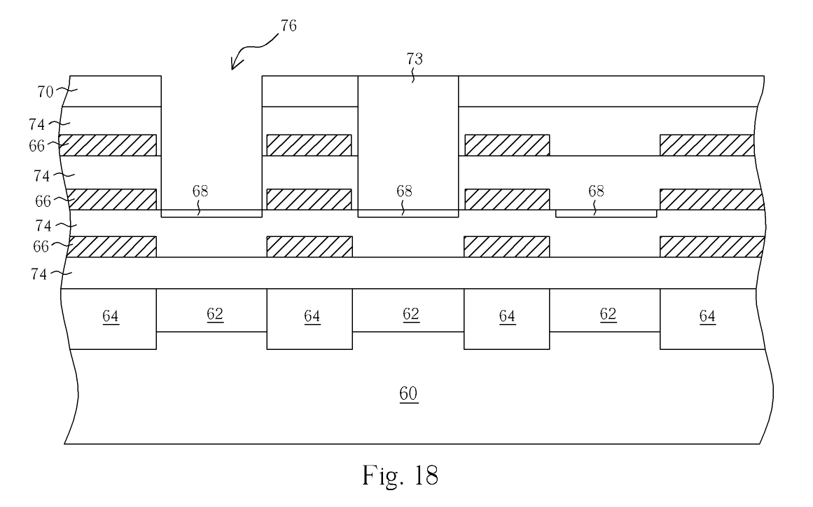

Next, as shown in FIG. 18, another pattern transfer process is performed by forming a patterned photoresist (not shown) on the passivation layer 70 and performing an etching process on the passivation layer 70 and the inter-metal dielectric 74 until reaching the etch stop layer 68 to form a trench 76 adjacent to the green color filter 73 in the passivation layer 70 and the inter-metal dielectric 74.

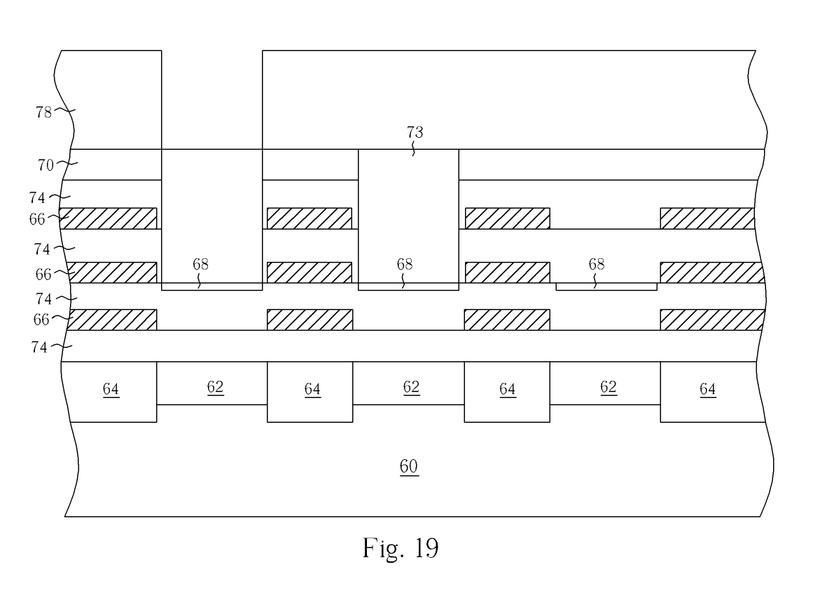

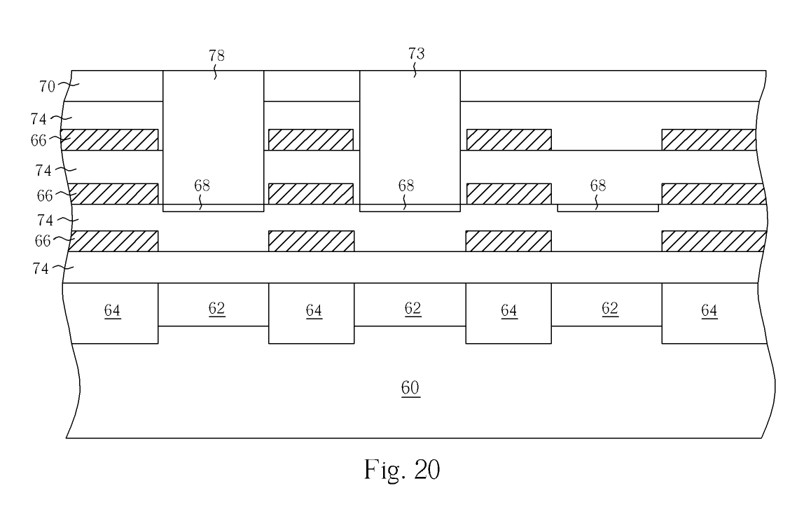

After the patterned photoresist is stripped, as shown in FIG. 19, another color film, such as a red color filter 78 composed of red dichroic film is deposited on the passivation layer 70 and within the trench 76. As shown in FIG. 20, a chemical mechanical polishing process is performed to planarize the red color filter 78 disposed on the surface of the passivation layer 70, such that the red color filter 78 deposited in the trench 76 is even with the surface of the passivation layer 70.

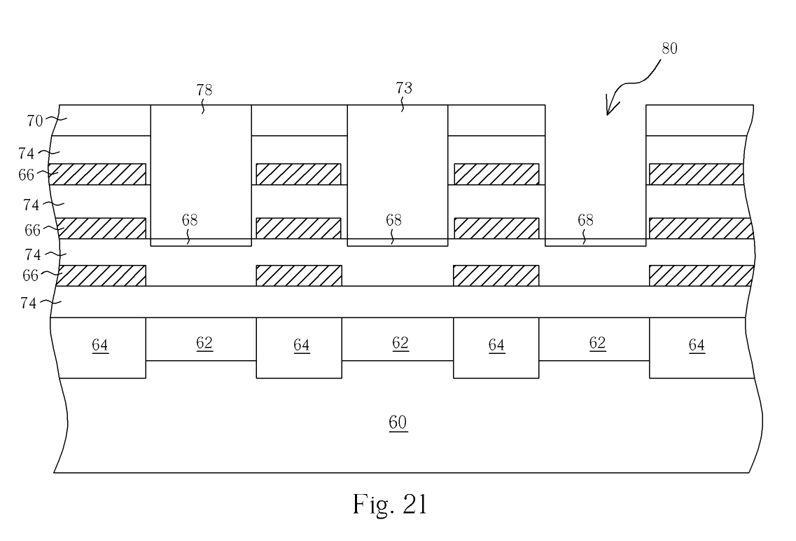

After the deposition of the red color filter 78, as shown in FIG. 21, another patterned transfer process is performed by forming a patterned photoresist (not shown) on the passivation layer 70, and performing an etching process on the passivation layer 70 and the inter-metal dielectric 74 until the etch stop layer 68 to form a trench 80 adjacent to the green color filter 73 in the passivation layer 70 and the inter-metal dielectric 74.

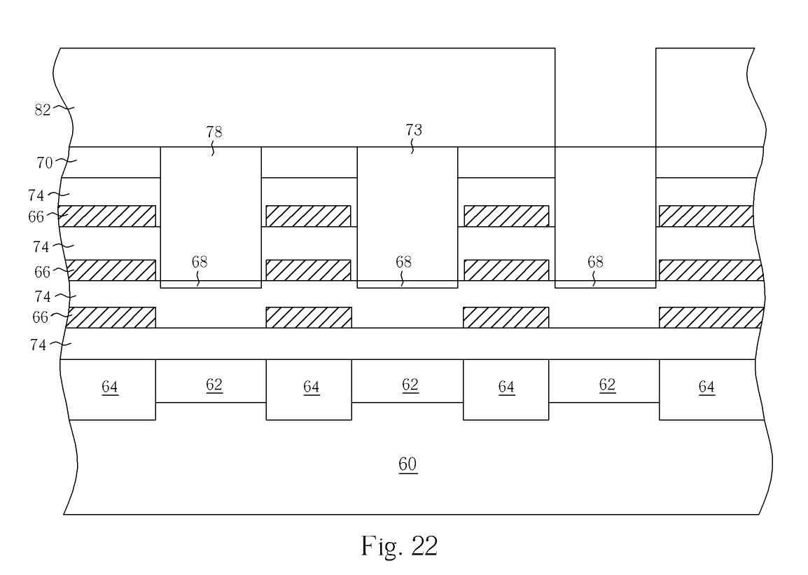

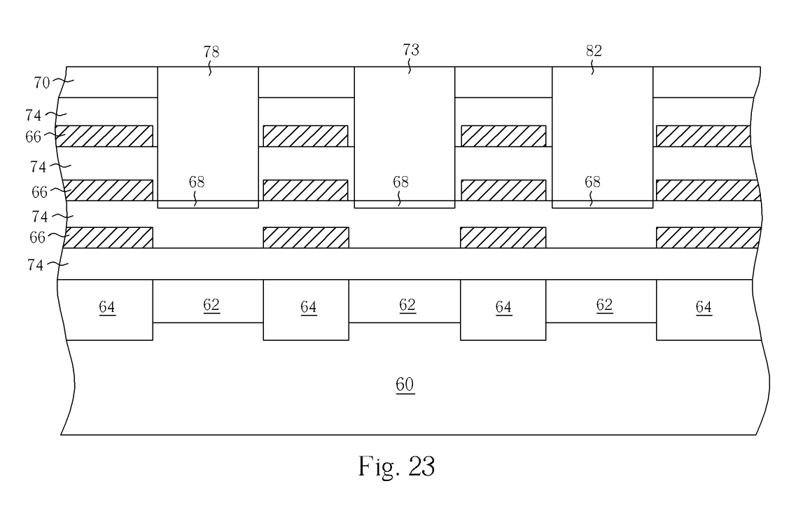

After the patterned photoresist is stripped, as shown in FIG. 22, a color film, such as a blue color filter 82 composed of blue dichroic film, is deposited on the passivation layer 70 and within the trench 80. Next, as shown in FIG. 23, a chemical mechanical polishing process is performed to planarize the blue color filter 82, such that the blue color filter 82 deposited in the trench 80 is even with the surface of the passivation layer 70. The fabrication of a color filter array containing three different colors is thus completed. Moreover, the processes described in the previously section can be performed repeatedly to fabricate a color filter array with many more colors and the details of which are not further explained herein for the sake of brevity.

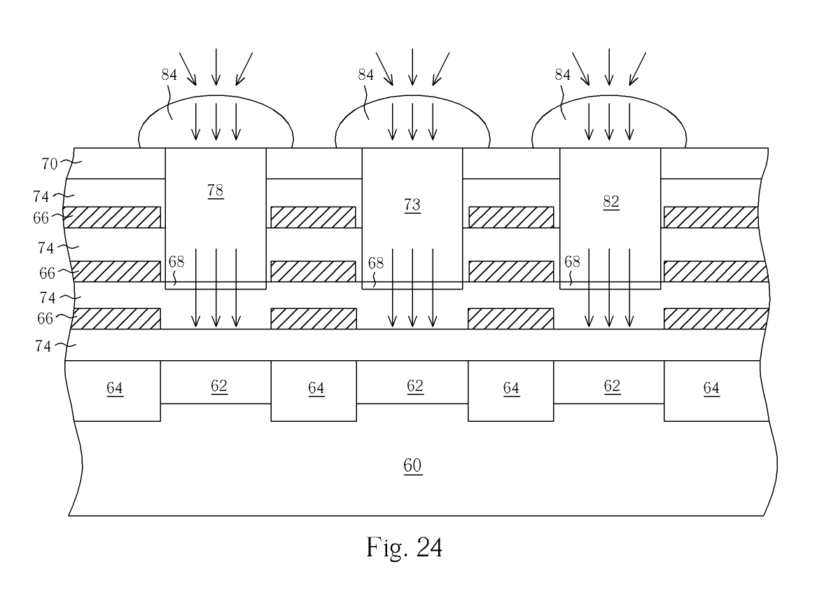

Next, as shown in FIG. 24, a plurality of microlenses 84 is disposed on the red color filter 78, green color filter 73, and blue color filter 82, in which light will be collected by the microlenses 84 and penetrate through color filters of different color and eventually reaching the photodiodes 62. The fabrication of a CMOS image sensor is thus completed.

In contrast to the conventional method of fabricating color filter arrays, the present invention first performs a pattern transfer process to form a trench in the dielectric layer disposed on the substrate, deposit a color filter in the trench, and performs a chemical mechanical polishing process to planarize the surface of the color filter. Ultimately, the present invention is able to reduce the effects of the problem of poor resolution and optically quality of color filters fabricated by conventional lift-off process or regular etching process and thereby offer improvements over the prior art. The present invention can be further applied to various optical products involving the utilization of color filters, including CMOS image sensors, charge coupled devices, and liquid crystal on silicon (LCOS) displays.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a color filter, comprising:
providing a substrate having a dielectric layer and a passivation thereon;
performing a first pattern transfer process to form a trench in the dielectric layer and the passivation layer;
forming a color filter in the trench, wherein the color filter partially covers the surface of the passivation layer; and
performing a chemical mechanical polishing process to planarize the color filter, such that the surface of the color filter is even with the surface of the passivation layer.

2. The method for fabricating a color filter of claim 1, wherein the color filter is a dichroic film.

3. The method for fabricating a color filter of claim 1, wherein the color filter comprises a red color filter, a green color filter, a blue color filter, a cyan color filter, a magenta color filter, and a yellow color filter.

4. The method for fabricating a color filter of claim 1, wherein the first pattern transfer process comprises:
forming a patterned photoresist on the surface of the passivation layer;
performing an etching process by utilizing the patterned photoresist as a mask to form a trench in the dielectric layer and the passivation layer; and
removing the patterned photoresist.

5. The method for fabricating a color filter of claim 1 further comprising performing a second pattern transfer process before performing the chemical mechanical polishing process.

6. The method for fabricating a color filter of claim 5, wherein the second pattern transfer process comprises:
forming a patterned photoresist on the color filter within the trench;
performing an etching process to remove part of the color filter above the passivation layer; and
removing the patterned photoresist.

7. The method for fabricating a color filter of claim 1 further comprising removing the dielectric layer and the passivation layer surrounding the color filter after performing the chemical mechanical polishing process.

8. The method for fabricating a color filter of claim 1, wherein the substrate comprises CMOS.

9. The method for fabricating a color filter of claim 1, wherein the dielectric layer is an inter-metal dielectric (IMD) of a CMOS image sensor.

10. The method for fabricating a color filter of claim 1, wherein the substrate is a silicon substrate of a liquid crystal on silicon (LCOS) display panel.

11. A CMOS image sensor, comprising:
a substrate;
a plurality of photodiodes, disposed on the substrate;
a dielectric layer, disposed on the substrate and the photodiodes;
a passivation layer, disposed on the dielectric layer;
a plurality of color filters, embedded in the dielectric layer and the passivation layer, wherein each color filter corresponds to each of the photodiodes; and
a plurality of microlenses, disposed on a portion of the passivation layer, wherein each microlens corresponds to each of the color filters.

12. The CMOS image sensor of claim 11 further comprising a plurality of metal layers disposed in the dielectric layer.

13. The CMOS image sensor of claim 11 further comprising a plurality of CMOS transistors disposed on the substrate.

14. The CMOS image sensor of claim 11, wherein the color filters comprise red color filters, green color filters, blue color filters, cyan color filters, magenta color filters, and yellow color filters.
